(19) United States
(12) Patent Application Publication
(10) Pub. No.: US 2008/0290447 A1
(43) Pub. Date: Nov. 27, 2008

(54) SEMICONDUCTOR DEVICE AND METHODS OF MANUFACTURING THE SAME

(75) Inventor: Tae-Woong Jeong, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 12/126,464

(22) Filed: May 23, 2008

(30) Foreign Application Priority Data
May 25, 2007 (KR) 10-2007-0050896

(51) Int. Cl. H01L 23/00; H01L 21/76

(52) U.S. Cl. 257/510; 438/421; 257/E21.54; 257/E23.001

(57) ABSTRACT

A method of making a semiconductor-oxide-nitride-oxide-semiconductor (SONOS) device by a process of growing Meta-stable poly silicon (MPS) regions is provided. Meta-stable poly silicon (MPS) regions are formed in the active region of a semiconductor substrate, dielectric materials are formed on the MPS regions, and control gates are formed on parts of the dielectric materials.

### CROSS-REFERENCE TO RELATED APPLICATION

This application claims priority to Korean Application No. 10-2007-0050896, filed on May 25, 2007, which is incorporated herein by reference in its entirety.

### BACKGROUND

1. Field of the Invention

The present invention relates to a semiconductor device and a method of manufacturing the same. More particularly, embodiments of the present invention relate to semiconductor-oxide-nitride-oxide-semiconductor (SONOS) devices.

2. Background of the Invention

The typical structure of a SONOS semiconductor device, as is shown in FIG. 1, is a transistor formed of silicon gate electrodes. The electrodes, such as source electrodes and drain electrodes, are formed on a semiconductor substrate with oxide-nitride-oxide (ONO) as a non-volatile insulating material interposed therebetween.

FIGS. 2A to 2C illustrate one example of a manufacturing process for providing the device structure of FIG. 1.

First, a semiconductor substrate 201 is formed with shallow trench isolations (STI) 203 for device isolation, as is illustrated in FIG. 2A.

Then, oxide-nitride-oxides (ONO) 205 formed of a dielectric material is deposited in the active region that is device isolated by the STIs 203 defined on the semiconductor substrate 201, as is illustrated in FIG. 2B.

Finally, the control gates 207 are formed on the ONOs 205, as is illustrated in FIG. 2C to realize the SONOS device.

However, this particular manufacturing approach is not without problems. In particular, high integration is performed so that the area occupied by a capacitance in the SONOS device is gradually reduced, so that the surface area of the capacitance is reduced, and so that a coupling ratio essential to the SONOS device is remarkably reduced. This can result in lower yields and can result in devices having lower reliability.

### SUMMARY OF EMBODIMENTS OF THE INVENTION

In general, embodiments of the present invention are directed to SONOS semiconductor devices provided by way of a process of growing a meta-stable poly-silicon (MPS) to increase the surface area of a capacitance, and to improve a coupling ratio of the SONOS device.

In accordance with an example embodiment, there is provided a semiconductor device, comprising STIs formed in a semiconductor substrate for device isolation. In addition, particle-shaped MPSs are formed in an active region isolated by the STIs. Dielectric materials are formed on the MPSs, and control gates are formed on parts of the dielectric materials. In an example embodiment, the poly particle-shaped MPS is formed by performing an MPS annealing process at a predetermined temperature at an N₂ atmosphere.

In another example embodiment, a method of manufacturing a semiconductor device is disclosed. The method comprises forming poly MPSs in an active region of a semiconductor substrate. Dielectric materials are formed on the poly MPSs, and control gates are provided on parts of the dielectric materials. In an example embodiment, the poly MPS is particle-shaped. The particle shape can be formed by performing an MPS annealing process at a predetermined temperature at an N₂ atmosphere.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

The above and other advantages and features of the present invention will become apparent from the following description of preferred embodiments given in conjunction with the accompanying drawings, in which:

FIG. 1 is a vertical sectional view illustrating the SONOS structure of a conventional semiconductor device;

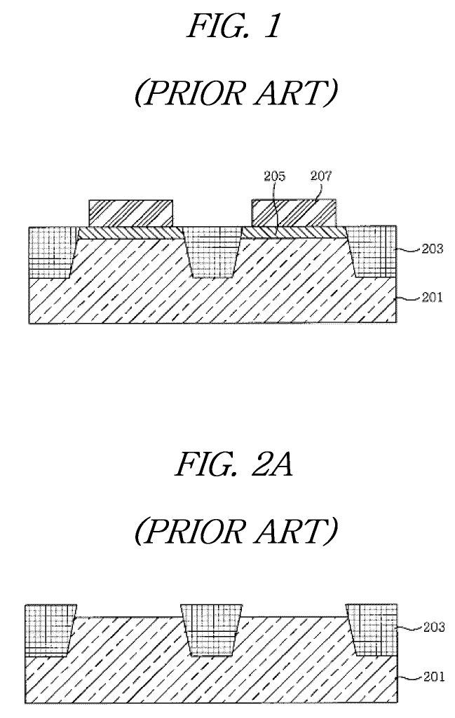

FIGS. 2A to 2C are vertical sectional views illustrating a method of manufacturing the SONOS structure of the conventional semiconductor device;

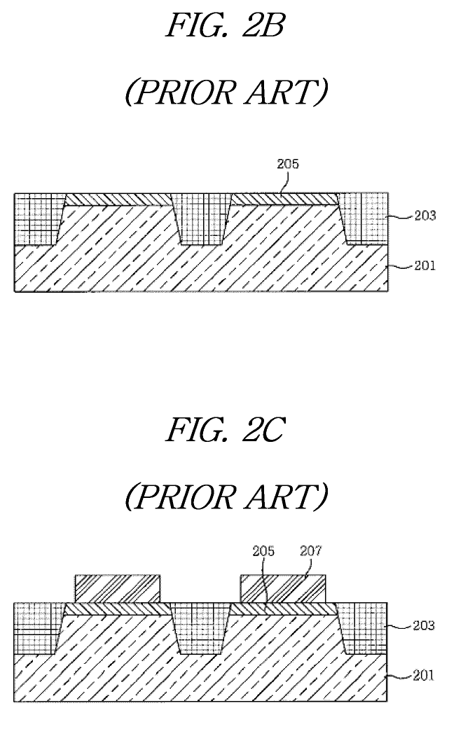

FIG. 3 is a vertical sectional view illustrating the SONOS structure of a semiconductor device according to an embodiment of the present invention; and

FIGS. 4A to 4D are vertical sectional views illustrating processes for describing one example of a method of manufacturing the SONOS structure of the semiconductor device.

### DETAILED DESCRIPTION OF EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

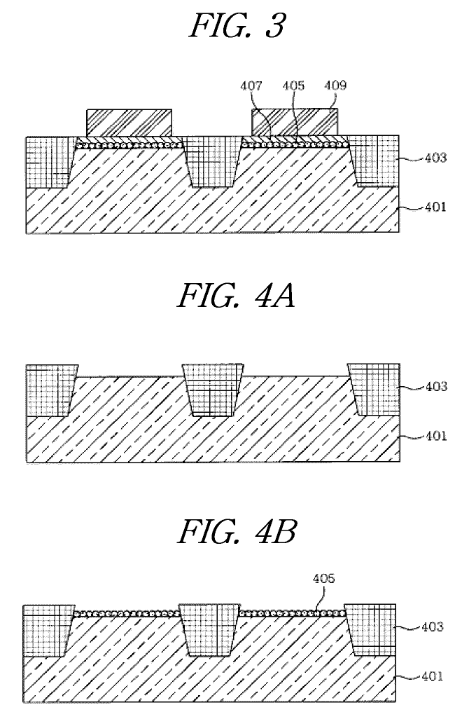

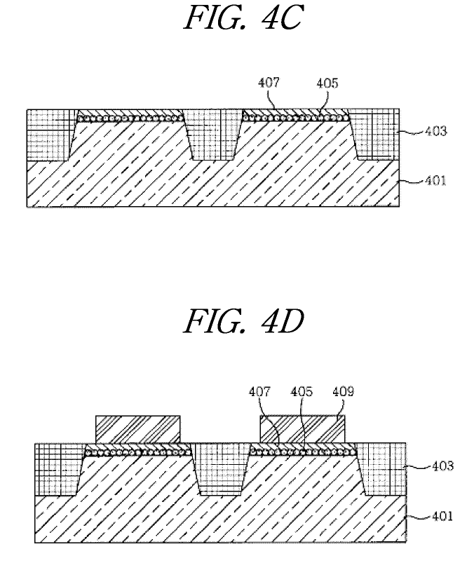

Referring generally to FIG. 3 and FIGS. 4A-4D, embodiments of the present invention relate to a improved semiconductor device, and processes for making the device. By way of overview, a process is performed to form the active region of a semiconductor substrate 401 and shallow trench isolations (STI) 403 for device isolation. A meta-stable poly silicon (MPS) annealing process is performed in the active region that is device isolated and defined by the STI 403 on the semiconductor substrate 401 at an N2 atmosphere so that poly particle-shaped MPSs 405 are formed. Then, oxide-nitride-oxide (ONO) 407 formed of a dielectric material are formed on the poly particle-shaped MPSs 405 and control gates 409 are formed on parts of the ONO 407 portions.

Referring next to FIG. 3 a vertical sectional view illustrating one example of a SONOS structure is shown.

In the illustrated example the poly particle-shaped MPSs 405 are formed in the active region of the semiconductor substrate 401 in the region in which the STIs 403 for device isolation are formed. In the illustrated embodiment, the poly particle-shaped MPSs 405 are formed by performing an MPS annealing process at an N₂ atmosphere and at a reaction temperature between approximately 800° C. and 1,500° C.

Then, ONOs 407, which are formed of a dielectric material, are formed on the poly particle-shaped MPSs 405.

As is further shown in the example embodiment, control gates 409 are formed on the parts of the ONO 407 surfaces.

In accordance with disclosed embodiments, a SONOS device is provided by using the poly particle-shaped MPS process described above. The resulting structure has an improved coupling ratio that is important to the operation of the SONOS element.

Reference is next made to FIGS. 4A to 4D, which are vertical sectional views illustrating processes for describing one example of a method for manufacturing the SONOS structure represented in the example embodiment of FIG. 3.

Referring first to FIG. 4A, the active region and the STIs 403 for isolation device are formed as shown in an example embodiment, a nitride layer is formed on the semiconductor substrate 401, which can comprise, for example, a silicon substrate, a ceramic substrate, or a polymer substrate. An etching process can be used to form an STI region 403 by a photoresist (PR) pattern. Next, an oxide layer is deposited by an appropriate process such as high density plasma, and a chemical mechanical polishing (CMP) process can be used to provide a substantially planar surface.

Next, a MPS annealing process can be performed in the portion of the active region that is device isolated and defined by the STIs 403 on the semiconductor substrate 401. In an example embodiment, the annealing process is performed at an N₂ atmosphere at a reaction temperature between approximately 800° C. and 1,500° C. so that the poly particle-shaped MPSs 405 are formed as illustrated in FIG. 4B.

In an example embodiment the ONOs 407, which are formed of a dielectric material, are deposited on the poly particle-shaped MPSs 405 to be formed as illustrated in FIG. 4C.

Finally, poly silicon can be deposited on substantially the entire surface of the semiconductor substrate 401, including the STIs 403 and the ONOs 407. An etching process can then be performed using the PR pattern formed on the poly silicon as a mask so that the control gates 409 are formed on the parts of the ONOs 407, for example as is illustrated in FIG. 4D.

The resulting SONOS device uses the poly particle-shaped MPS process so that it is possible to prevent the area occupied by a capacitance in the SONOS device from being gradually reduced and to prevent the surface area of the capacitance from being reduced. In this way it is possible to prevent the coupling ratio essential to the SONOS device from remarkably deteriorating and to improve the yield and reliability of the semiconductor device.

In summary, disclosed embodiments provide a SONOS device by performing the MPS annealing process in the active region that is device isolated by the STIs to form the embossed surface area of the poly particle-shaped MPS. This permits the surface area of the capacitance to be increased in comparison with a flat ONO structure and to improve the coupling ratio of the SONOS device. Again, this improves the yield and reliability of the resulting semiconductor device.

In addition, disclosed embodiments permit for high integration so that it is possible to further improve the yield and the reliability of the semiconductor device. Other advantages include reduced manufacturing cost, and increased performance of the semiconductor device.

While the invention has been shown and described with respect to the preferred embodiments, it will be understood by those skilled in the art that various changes and modifications may be made without departing from the spirit and scope of the invention as defined in the following claims.

What is claimed is:

1. A semiconductor device, comprising:
shallow trench isolations (STI) formed in a semiconductor substrate in a manner so as to provide device isolation in an active region;
particle-shaped meta-stable poly silicon (MPS) regions disposed on portions of the active region that are device isolated by the STIs;
one or more dielectric materials disposed on the MPS regions; and
control gates disposed on parts of the dielectric materials.

2. The semiconductor device of claim 1, wherein the STI includes a nitride layer on the semiconductor substrate.

3. The semiconductor device of claim 1, wherein the poly particle-shaped MPS region is formed by performing an MPS annealing process at a specific temperature at an N2 atmosphere.

4. The semiconductor device of claim 3, wherein the specific temperature is between 800° C. and 1,500° C.

5. The semiconductor device of claim 1, wherein the dielectric material is an oxide-nitride-oxide (ONO).

6. A method of manufacturing a semiconductor device, comprising:
forming meta-stable poly silicon (MPS) regions in an active region of a semiconductor substrate;
forming dielectric materials on the MPS regions; and
forming control gates on a least portions of the dielectric materials.

7. The method of claim 6, wherein the MPS region is particle-shaped.

8. The method of claim 7, wherein the particle shape is formed by performing an MPS annealing process at a specific temperature at an N2 atmosphere.

9. The method of claim 8, wherein the specific temperature is between 800° C. and 1,500° C.

10. The method of claim 6, wherein the dielectric material is oxide-nitride-oxide (ONO).
